(19) United States
(12) Patent Application Publication
(10) Pub. No.: US 2016/0315256 A1
(43) Pub. Date: Oct. 27, 2016

(54) V-SHAPE RESISTIVE MEMORY ELEMENT

(71) Applicant: HEWLETT PACKARD ENTERPRISE DEVELOPMENT LP, Houston, TX (US)

(72) Inventors: Ning Ge, Palo Alto, CA (US); Jianhua Yang, Palo Alto, CA (US); Chaw Sing Ho, Singapore (SG)

(73) Assignee: HEWLETT PACKARD ENTERPRISE DEVELOPMENT LP, Houston, TX (US)

(21) Appl. No.: 15/103,604

(22) PCT Filed: Dec. 13, 2013
(86) PCT No.: PCT/US2013/074997

§ 371 Date: Jun. 10, 2016

(51) Int. Cl. H01L 45/00; H01L 27/24

(52) U.S. Cl. CPC H01L 45/1273; H01L 45/085; H01L 45/1233; H01L 45/145; H01L 45/1608; H01L 27/2463

(57) ABSTRACT

A resistive memory element is provided, having a bottom electrode, a top electrode, and an active region sandwiched therebetween. The resistance memory element has a V-shape. Methods of manufacturing the V-shape resistive memory element and crossbar structures employing the V-shape resistive memory element are also provided.

### BACKGROUND

Resistive memory elements can be programmed to different resistance states by applying programming energy. After programming, the state of the resistive memory elements can be read and remains stable over a specified time period. Large arrays of resistive memory elements can be used to create a variety of resistive memory devices, including non-volatile solid state memory, programmable logic, signal processing, control systems, pattern recognition devices, and other applications. Examples of resistive memory devices include valence change memory and electrochemical metallization memory, both of which involve ionic motion during electrical switching and belong to the category of memristors.

Memristors are devices that can be programmed to different resistive states by applying a programming energy, for example, a voltage or current pulse. This energy generates a combination of electric field and thermal effects that can modulate the conductivity of both non-volatile switch and non-linear select functions in a memristive element. After programming, the state of the memristor can be read and remains stable over a specified time period.

### BRIEF DESCRIPTION OF THE DRAWINGS

FIG. 1 depicts a V-shape resistive memory element, here, a memristor, according to an example.

FIGS. 2A-2B depict, respectively, a cross-sectional view and a top view of the geometry of a pit etched into silicon for use with manufacturing a V-shape resistive memory element, such as a memristor, according to an example.

FIGS. 3A-3H depict cross-sectional views of a process sequence used to manufacture a V-shape resistive memory element, such as a memristor, according to an example.

FIG. 4 is a flow chart, depicting a method for manufacturing a V-shape resistive memory device, such as a memristor, according to an example.

FIG. 5 is a view similar to that of FIG. 1, but showing a portion of a crossbar structure, with three V-shape resistive memory elements, according to an example.

FIG. 6 is a top plan view of a crossbar structure employing the V-shape resistive memory elements, according to an example.

### DETAILED DESCRIPTION

In the following description, numerous details are set forth to provide an understanding of the examples disclosed herein. However, it will be understood that the examples may be practiced without these details. While a limited number of examples have been disclosed, it should be understood that there are numerous modifications and variations therefrom. Similar or equal elements in the Figures may be indicated using the same numeral.

As used in the specification and claims herein, the singular forms “a,” “an,” and “the” include plural referents unless the context clearly dictates otherwise.

As used in this specification and the appended claims, “approximately” and “about” mean a ±10% variance caused by, for example, variations in manufacturing processes.

In the following detailed description, reference is made to the drawings accompanying this disclosure, which illustrate specific examples in which this disclosure may be practiced. The components of the examples can be positioned in a number of different orientations and any directional terminology used in relation to the orientation of the components is used for purposes of illustration and is in no way limiting. Directional terminology includes words such as “top,” “bottom,” “front,” “back,” “leading,” “trailing,” etc.

It is to be understood that other examples in which this disclosure may be practiced exist, and structural or logical changes may be made without departing from the scope of the present disclosure. Therefore, the following detailed description is not to be taken in a limiting sense. Instead, the scope of the present disclosure is defined by the appended claims.

Resistive memory elements can be used in a variety of applications, including non-volatile solid state memory, programmable logic, signal processing, control systems, pattern recognition, and other applications.

As used in the specification and appended claims, the term “resistive memory elements” refers broadly to programmable non-volatile resistors where the switching mechanism involves atomic motion, including valance change memory, electrochemical metallization memory, and others. An example of a resistive memory element may be a memristor.

Memristors, or memristive devices, are nano-scale devices that may be used as a component in a wide range of electronic circuits, such as memories, switches, and logic circuits and systems. In a memory structure, a crossbar of memristors may be used. For example, when used as a basis for memories, the memristor may be used to store a bit of information, 1 or 0, corresponding to whether the memristor is in its high or low resistance state (or vice versa). When used as a logic circuit, the memristor may be employed as configuration bits and switches in a logic circuit that resembles a Field Programmable Gate Array, or may be the basis for a wired-logic Programmable Logic Array. It is also possible to use memristors capable of multi-state or analog behavior for these and other applications.

When used as a switch, the memristor may either be in a low resistance (closed) or high resistance (open) state in a cross-point memory. During the last few years, researchers have made great progress in finding ways to make the switching function of these memristors behave efficiently. For example, tantalum oxide (TaOₓ)-based memristors have been demonstrated to have superior endurance over other nano-scale devices capable of electronic switching. In lab settings, tantalum oxide-based memristors are capable of over 10 billion switching cycles.

A memristor may comprise a switching material, such as TiOₓ or TaOₓ, sandwiched between two electrodes. Memristive behavior is achieved by the movement of ionic species (e.g., oxygen ions or vacancies) within the switching material to create localized changes in conductivity via modulation of a conductive filament between two electrodes, which results in a low resistance “ON” state, a high resistance “OFF” state, or intermediate states. Initially, when the memristor is first fabricated, the entire switching material may be nonconductive. As such, a forming process may be required to form the conductive channel in the switching material between the two electrodes. A known forming process, often called “electroforming”, includes applying a sufficiently high (threshold) voltage across the electrodes for a sufficient length of time to cause a nucleation and formation of a localized conductive channel (or active region) in the switching material. The threshold voltage and the length of time required for the forming process may depend upon the type of material used for the switching material, the first electrode, and the second electrode, and the device geometry. Material composition and stack structure of the multilayers can be engineered to achieve the so-called electroforming-free, forming-free or electroforming-less devices, where the voltages used for electroforming are relatively small and comparable to those used in the subsequent switching. Still, some sort of conduction channel(s) or filament(s) (not shown) may be created by the applied voltage during this first electrical operation.

Metal or semiconductor oxides may be employed in memristive devices; examples include either transition metal oxides, such as tantalum oxide, titanium oxide, yttrium oxide, hafnium oxide, niobium oxide, zirconium oxide, or other like oxides, or non-transition metal oxides, such as aluminum oxide, calcium oxide, magnesium oxide, dysprosium oxide, lanthanum oxide, silicon dioxide, or other like oxides. Further examples include metal nitrides, such as aluminum nitride, gallium nitride, tantalum nitride, and silicon nitride.

Memristive devices may include a continuous oxide film between the electrodes. In the first electrical operation, filaments/ionic diffusion are formed in the oxide film between the electrodes in a random fashion, much like lightning, that may take the path of least resistance. This random path causes variations in the memristor I-V characteristics from switching cycle to cycle and especially from device to device. Older memristive or non-volatile resistive memory devices that are either unipolar or bipolar tend to have this random conductive path between the electrodes; that is, the vacancies have to find their own path to the opposite electrodes. This randomness in the conductive channel formation may cause variability in reproducibility and/or reliability issues, which is one of the biggest challenges in the commercialization of these devices.

For the conventional memristor, the device is flat, being a planar metal-oxide-metal structure based on a bottom electrode (BE; metal), an active region (oxide), and atop electrode (TE; metal). A filament formed in the oxide is the conduction path for the device with oxygen vacancy. The formation of the filament is a random process in the oxide through electrical, chemical, and thermal interaction. Similar considerations may be true for nitride-based memristors.

As a result of the random filament formation process, forming and switching of the memristor is not under full control. Therefore, variation of forming and switching behavior is observed, which is one of the biggest issues with memristive devices. Various efforts have been tried, such as the introduction of planting seeds of switching centers by thermal diffusion to control the formation of switching channels.

In accordance with the teachings herein, a V-shape memristor architecture is provided. The device architecture may be manufactured, using industry established processes.

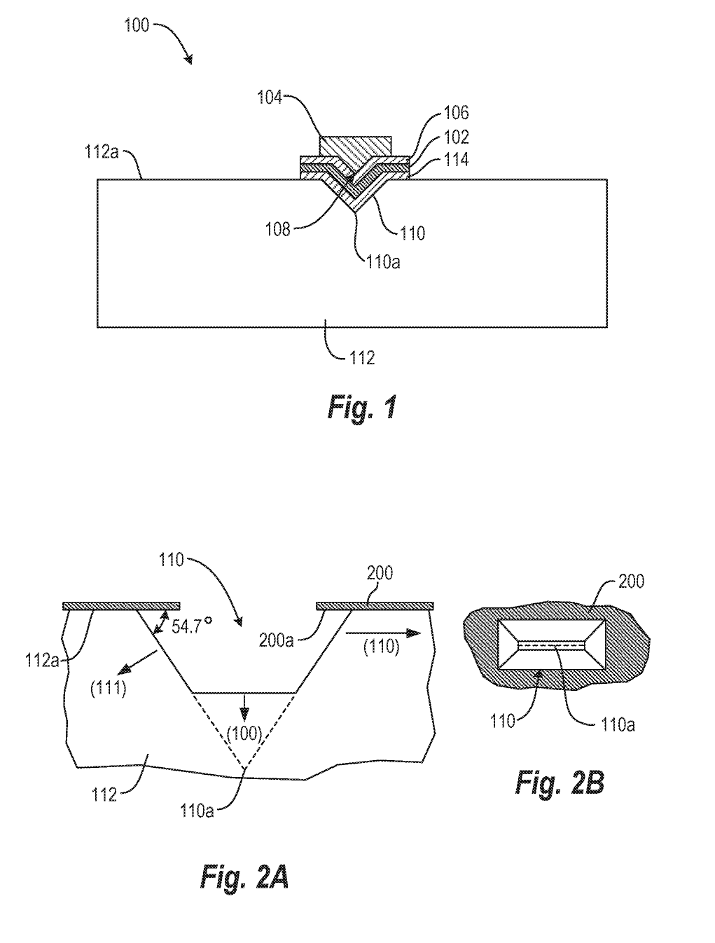

The resistance memory element, here, a memristor, is depicted in FIG. 1. The memristor 100 has a bottom electrode 102, a top electrode 104, and an active region 106 sandwiched the bottom electrode and the top electrode, as described above. The memristor 100 has a V-shape, in which the V-tip 108 of the top electrode 104 may lead to a concentrated electric field like in an electron gun tip. This may help the channel formation in the proximity region around the tip of the V-shape. Therefore, a more controlled and uniform filament, or channel, formation may be achieved. Simulation studies suggest that the electric field is concentrated on sharp corners, where the filament may prefer to form.

The memristor 100 is formed in a V-shape groove or pit 110 formed in a major surface 112a of a silicon substrate 112. The (100) planes of the silicon substrate 112 are parallel to the major surface 112a. The memristor 100 is separated from the silicon substrate 112 by a dielectric layer 114.

The device architecture described herein may involve anisotropic wet silicon etching. The Si geometry may be defined by crystal planes of substrate etch rates of the (100) and (110) planes much greater than that of the (111) plane, as shown in FIGS. 2A-2B.

Any chemical solution with a pH value of greater than 12 may be used as an anisotropic etching solution. Due to the requirement of good anisotropic etching characteristics, such as a high etching rate of silicon, high etching rate dependencies on crystallographic orientations, smooth etched surface, low etching rate of mask material, compatibility with CMOS processes, low toxicity, and ease of handling, tetramethyl ammonium hydroxide (TMAH; (CH₃)₄NOH) and potassium hydroxide (KOH) have been the most commonly used etchants for silicon device fabrication.

The profile of the etch pit 110 may be determined by definition of an etch mask 200. For example, a V-shape pit may be formed if the etch time is long enough to allow the etch to reach the pit bottom. It will be appreciated that the etch pit shown in FIGS. 2A-2B is shown during etching that has not yet achieved the V-shape. The termination of the V is indicated at 110a, extending the partially etched profile with dashed lines. Other pit profiles may be tuned also by controlling the wet etch mask and wet etch rate and time.

The use of an anisotropic etchant, with the (100) planes of silicon parallel to the major surface in conjunction with the etch mask 200 usually leads to underetching of the etch mask, as shown at 200a in FIG. 2A. The angle of the slope formed by the (111) planes to the (100) planes is the characteristic 54.7°. At the end of the etch, the (100) planes disappear, resulting in the V-shape, terminating at the apex 110a of the V, as shown by the dashed lines in FIGS. 2A-2B.

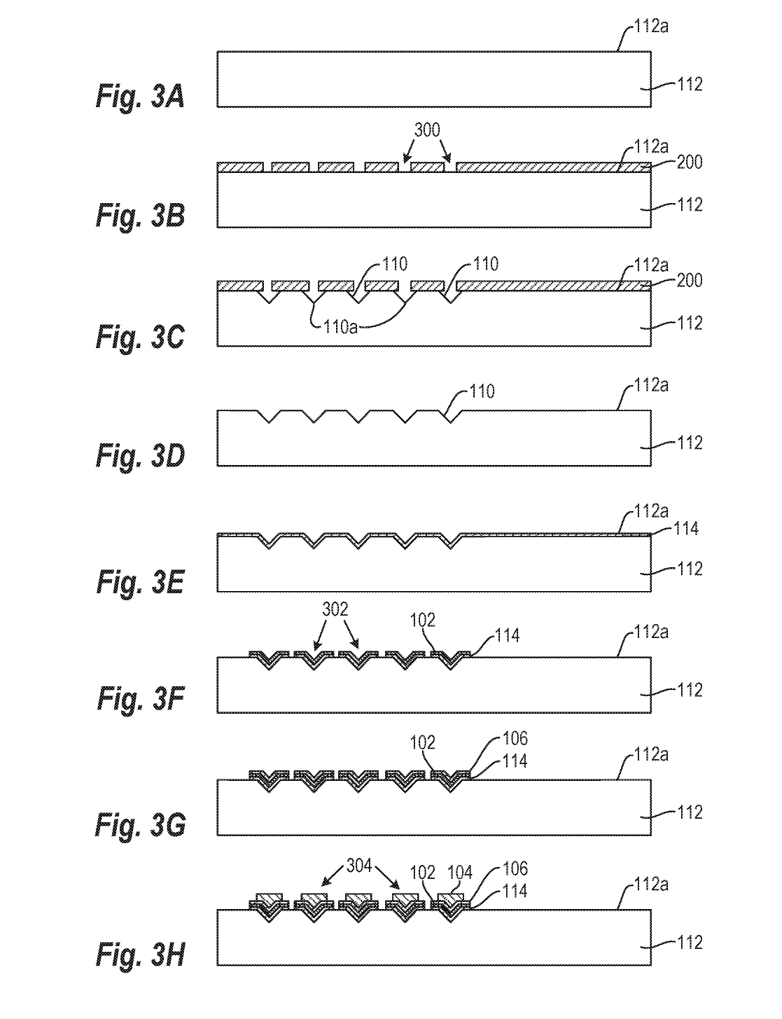

A more detailed process flow is illustrated in FIGS. 3A-3H.

In FIG. 3A, the silicon substrate 112 is provided. The silicon substrate 112 may have major surface 112a with (100) planes parallel to the major surface. The silicon substrate 112 may be with Front End of Line (FEOL) fabricated CMOS devices already or a half-finished wafer to share certain processes later.

In FIG. 3B, silicon etch mask 200 is formed the major surface 112a of the silicon substrate 112 and is patterned to form openings 300 that expose portions 112a of the silicon substrate. Examples of suitable silicon etch mask materials include, but are not limited to, photoresist materials and hard masks, such as Si₃N₄ thin films. The silicon etch mask 200 may be formed on the silicon substrate by any number of processes, including, but not limited to, photoresist deposition and Chemical Vapor Deposition (CVD).

In FIG. 3C, a silicon anisotropic etch is performed, forming V-grooves 110. Examples of suitable Si anisotropic etchants include, but are not limited to, tetramethyl ammonium hydroxide and potassium hydroxide, although other suitable anisotropic etchants may also be used.

In FIG. 3D, the silicon etch mask 200 is removed and the substrate surface 112a is cleaned, using conventional wafer processing.

In FIG. 3E, dielectric layer 114 is formed on the surface 112a and in the grooves 110. The dielectric layer 114 may be conformal. The dielectric layer 114 may be an interlayer dielectric, such as SiO₂ or Si₃N₄, and formed by CVD or thermal oxidation.

In FIG. 3F, bottom electrode 102 is formed on the dielectric layer 114, defined lithographically, and etched so as to form isolated regions 302. Examples of materials for electrodes 102 include, but are not limited to, aluminum (Al), copper (Cu), platinum (Pt), tungsten (W), gold (Au), titanium (Ti), silver (Ag), ruthenium dioxide (RuO₂), titanium nitride (TiN), tungsten nitride (WN₂), tantalum (Ta), hafnium nitride (HfN), niobium nitride (NbN), tantalum nitride (TaN), and the like. The thickness of the electrode 102 may be in the range of about 10 nm to a few micrometers. Examples of forming the bottom electrode 102 include, but are not limited to, electroplating, sputtering, evaporation, ALD (atomic layer deposition), co-deposition, chemical vapor deposition, IBAD (ion beam assisted deposition), oxidation of pre-deposited materials, or any other film deposition technology. Methods for defining the bottom electrode 102 lithographically may be conventional. Etching may be performed by plasma dry etching.

In FIG. 3G, active layer 106 is formed on the bottom electrode 102, defined lithographically, and etched. The active layer 106, also called the switching layer, is so called because it supports switching between two states, “low” resistivity and “high” resistivity, and thus between “ON” and “OFF”, respectively. By “low” and “high” resistivity is meant the relative resistance of the active layer 106, where “low” and “high” are relative terms. Typically, the difference in resistivity is on the order of at least 10 fold. It is within the active layer 106 that one (or more) conducting channel(s) (not shown) is(are) formed. Examples of suitable materials for forming the active layer 106 include the oxides and nitrides listed above. Examples of forming the active layer 106 include, but are not limited to, e-beam deposition, sputter deposition, atomic layer deposition (ALD), and the like. Methods for defining the active layer 106 lithographically may be conventional. Etching may be performed by plasma dry etching.

In FIG. 3H, top electrode 104 may formed on the active layer 106, defined lithographically, and etched. In this manner, cells 304 are formed by the bottom electrode 102, the active layer 106, and the top electrode 104. Examples of suitable metals for forming the top electrode 104 are selected from the same list as those used for forming the bottom electrode 102, and may be the same or different. The thickness of the top electrode 104 may be in the same range as for the bottom electrode 102. Examples of forming the top electrode 104 may be the same as those for forming the bottom electrode 102. Methods for defining the top electrode 104 lithographically may be conventional. Etching may be performed by plasma dry etching.

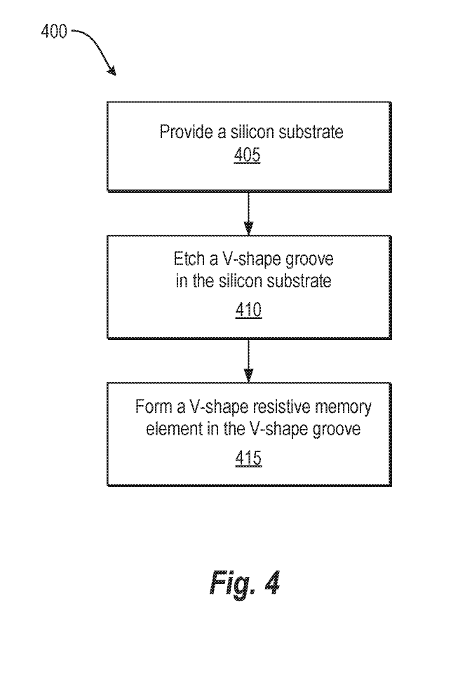

A method for manufacturing a V-shape resistive memory element, specifically, a memristor, is shown in the process flow chart depicted in FIG. 4. The method 400 may be achieved by first providing 405 a silicon substrate. The silicon substrate may have a major surface in which the (100) planes are parallel to the major surface.

The method 400 continues with etching 410 a V-shape groove in the silicon substrate. As discussed above, the V-shape groove is etched using an anisotropic etchant, such as tetramethyl ammonium hydroxide or potassium hydroxide. The process includes depositing a silicon etch mask on the major surface, patterning the silicon etch mask to expose portions of the silicon substrate, and etching into the silicon substrate with the anisotropic etchant.

The method 400 concludes with forming 415 the V-shape resistive memory element, or memristor, in the V-shape groove. The V-shape memristor is formed by forming a dielectric layer in at least the V-shape grooves; forming a bottom electrode on the dielectric layer; forming an active region on the bottom electrode; and forming a top electrode on the active region. The dielectric layer is formed by either depositing an interlayer dielectric or growing a thermal oxide. The formation of the bottom electrode, the active layer, and the top electrode have all been described above.

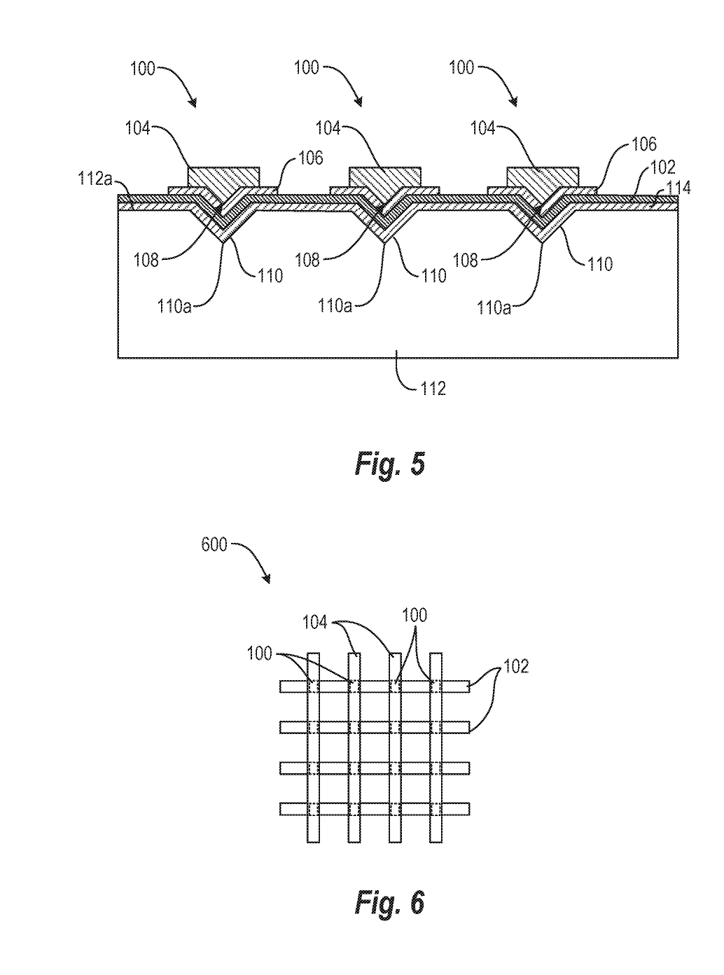

The device 100 depicted in FIG. 1 may find application in non-crossbars, where density is not critical, but repeatability and energy are. Alternatively, the device 100 may find application in crossbars. FIG. 5 illustrates a cross-sectional view of three resistive memory elements, here, memristors, on the silicon substrate, much like the device 100 depicted in FIG. 1.

A crossbar is a structure having a set of bottom conductors 102 and a set of top conductors 104 crossing the set of bottom conductors at a non-zero angle. In FIG. 5, a row of bottom conductors 102 is depicted, with columns of top conductors 104 each perpendicular to the plane of the drawing. Each crossing of a top conductor 104 and a bottom conductor forms a junction; at each junction, a resistive memory element, or memristor, 100 may be formed.

FIG. 6 is a top plan view of a crossbar 600, showing the bottom conductors 102 and the top conductors 104. The resistive memory elements, or memristors, 100 are shown as dashed rectangles.

By tuning the deposition method and thickness, it is expected that the desired architecture may be achieved. For example, for the bottom electrode and active layer, the thickness and uniformity may be carefully controlled. For the top electrode deposition, a slightly thicker one than the bottom electrode may be desired to ensure that a good acute tip may be formed.

The V-shape architecture is expected to provide several advantages, including reduced variation from device to device since the memristor electroforming and switching are more predictable and repeatable due to the V-shape tip defined channel. Device endurance may be enhanced due to avoiding random hard breakdown leading to irrevocable failure. The architecture is easy to implement in fabrication and is compatible with industry processes (can have both V-shape memristor and conventional memristor in same die). The memristor dimension can be smaller than the technology Critical Dimension, (CD) since the memristor is confined in a space defined by etch mask (using technology CD) then shrunk by ILD (interlayer dielectric) or oxide growth. Smaller device size leads to lower operation current and energy.

What is claimed is:

1. A resistive memory element including a bottom electrode, a top electrode, and an active region sandwiched therebetween, the resistance memory element having a V-shape.

2. The resistive memory element of claim 1, comprising a memristor.

3. The resistive memory element of claim 2, wherein the active region is an oxide or a nitride.

4. The resistive memory element of claim 3, wherein the oxide is a transition metal oxide selected from the group consisting of tantalum oxide, titanium oxide, yttrium oxide, hafnium oxide, niobium oxide, and zirconium oxide or a non-transition metal oxide selected from the group consisting of aluminum oxide, calcium oxide, magnesium oxide, dysprosium oxide, lanthanum oxide, and silicon dioxide; and wherein the nitride is a metal nitride selected from the group consisting of aluminum nitride, gallium nitride, tantalum nitride, and silicon nitride.

5. The resistive memory element of claim 1, formed on a silicon substrate.

6. The resistive memory element of claim 5, wherein the silicon substrate has a V-shape pit formed in a surface thereof, and wherein the resistive memory element is formed in the V-shape pit.

7. The resistive memory element of claim 6, wherein an interlayer dielectric isolates the resistive memory element from the silicon substrate.

8. A method for manufacturing a V-shape resistive memory element, the method including:
providing a silicon substrate;
etching a V-shape groove in the silicon substrate; and
forming the V-shape resistive memory element in the V-shape groove.

9. The method of claim 8, wherein the resistive memory element is a memristor.

10. The method of claim 8, wherein etching the V-shape groove includes providing the silicon substrate that has its (100) parallel to a major surface, depositing a silicon etch mask on the major surface, patterning the silicon etch mask to expose portions of the silicon substrate, and etching into the silicon substrate with an anisotropic etchant.

11. The method of claim 7, wherein forming the V-shape resistive memory element includes:
forming a dielectric layer in at least the V-shape grooves;
forming a bottom electrode on the dielectric layer;
forming an active region on the bottom electrode; and
forming a top electrode on the active region.

12. The method claim 11, wherein forming the dielectric layer is performed by either depositing an interlayer dielectric or growing a thermal oxide.

13. A crossbar including an array of approximately first conductors and an array of approximately second conductors, the array of first conductors crossing the array of second conductors at a non-zero angle, each intersection of a first conductor with a second conductor forming a junction, with a resistive memory element having a V-shape at each junction each resistive memory element comprising one of the first conductors as a bottom electrode, one of the second conductors as a top electrode, and an active region sandwiched therebetween.

14. The crossbar of claim 13, wherein the resistive memory element comprises a memristor.

15. The crossbar of claim 13, wherein the V-shape is formed in a silicon substrate, wherein an interdielectric isolates the resistive memory element from the silicon substrate, and wherein the active region is an oxide or a nitride.
